(19) United States
(12) Patent Application Publication
(10) Pub. No.: US 2024/0234504 A9
(43) Pub. Date: Jul. 11, 2024

(54) SEMICONDUCTOR DEVICE AND POWER CONVERSION DEVICE

(71) Applicant: Mitsubishi Electric Corporation, Tokyo (JP)

(72) Inventors: Seiya SUGIMACHI, Tokyo (JP); Kazufumi OKI, Tokyo (JP); Okinori INOUE, Tokyo (JP); Kazuhiro KAWAHARA, Tokyo (JP); Kosuke YAMAGUCHI, Tokyo (JP)

(73) Assignee: Mitsubishi Electric Corporation, Tokyo (JP)

(21) Appl. No.: 18/451,819

(22) Filed: Aug. 17, 2023

(30) Foreign Application Priority Data
Oct. 24, 2022 (JP) 2022-169930

(51) Int. Cl. H01L 29/06; H01L 29/739; H01L 29/78; H02M 7/5387

(52) U.S. Cl. CPC H01L 29/0696; H01L 29/0603; H01L 29/7393; H01L 29/7801; H02M 7/53875

(57) ABSTRACT

The object is to provide a technology that can shorten a routing length of a gate wire connecting a control IC that controls driving first and second semiconductor elements that are connected in parallel with each other, to a gate pad of one of the first and second semiconductor elements disposed distant from the control IC. A first semiconductor element and a second semiconductor element are disposed so that a long side of the first semiconductor element faces a side of the second semiconductor element, and a HVIC or a LVIC, the first semiconductor element, and the second semiconductor element are disposed in this order in a direction orthogonal to a first direction, the gate pad is disposed on the first semiconductor element on one side in the first direction, and the gate pad is disposed on the second semiconductor element on the other side in the first direction.

### BACKGROUND OF THE INVENTION

### Field of the Invention

The present disclosure relates to a semiconductor device and a power conversion device.

### DESCRIPTION OF THE BACKGROUND ART

Conventional semiconductor devices include, as a switching device, a semiconductor device in which metal-oxide-semiconductor field-effect transistors (MOSFETs) are connected in parallel with insulated gate bipolar transistors (IGBTs) and the MOSFETs and the IGBTs are controlled by a single drive signal (see, for example, Japanese Patent Application Laid-Open No. 2013-125806).

According to the technology described in the aforementioned application, each of the IGBTs and the MOSFETs is of a rectangle having a short side extending in a first direction and having a long side in a direction orthogonal to the first direction in a top view. Gate control circuits (corresponding to control integrated circuits (ICs)) controlling driving of the MOSFETs and the IGBTs, the IGBTs, and the MOSFETs are disposed in this order in the direction orthogonal to the first direction. This increases, particularly, distances between the gate control circuits and gate pads on the MOSFETs that are distant from the gate control circuits, and increases the routing length of gate wires connecting these. Thus, various problems have been created.

### SUMMARY

The object of the present disclosure is to provide a technology that can shorten a routing length of a gate wire. The gate wire connects a control IC that controls driving of a first semiconductor element and a second semiconductor element that are connected in parallel with each other, to a gate pad of one of the first and second semiconductor elements which is disposed distant from the control IC.

A semiconductor device according to the present disclosure includes a first semiconductor element and a second semiconductor element that are connected in parallel with each other; a control integrated circuit being of a rectangle; a first gate pad; a second gate pad; a first wire; and a second wire. The control integrated circuit controls driving of the first semiconductor element and the second semiconductor element, the control integrated circuit being of the rectangle having a long side extending in a first direction in a top view. The first gate pad is disposed on the first semiconductor element, and receives a signal for controlling the driving of the first semiconductor element. The second gate pad is disposed on the second semiconductor element, and receives a signal for controlling the driving of the second semiconductor element. The first wire connects the control integrated circuit to the first gate pad. The second wire connects the control integrated circuit to the second gate pad. The first semiconductor element is of a rectangle having a long side extending in the first direction in the top view. The second semiconductor element is of a quadrangle having a side extending in the first direction in the top view. The first semiconductor element and the second semiconductor element are disposed so that the long side of the first semiconductor element faces the side of the second semiconductor element, and the control integrated circuit, the first semiconductor element, and the second semiconductor element are disposed in this order in a direction orthogonal to the first direction. The first gate pad is disposed on the first semiconductor element on one side in the first direction. The second gate pad is disposed on the second semiconductor element on the other side in the first direction.

The present disclosure can shorten a routing length of a second wire that connects a control IC to the second gate pad of the second semiconductor element which is disposed distant from the control IC.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a top view illustrating an internal structure of a semiconductor device according to Embodiment 1;

FIG. 2 is a top view illustrating a part of the internal structure of the semiconductor device according to Embodiment 1;

FIG. 3 is a circuit diagram illustrating a part of a circuit configuration of the semiconductor device according to Embodiment 1;

FIG. 4 is a circuit diagram illustrating causes of overvoltage breakdowns and malfunctions that are caused by a dV/dt of MOSFETs;

FIG. 5 is a circuit diagram illustrating parasitic oscillations when the MOSFETs and IGBTs are driven in parallel;

FIG. 6 illustrates an allowable current when a SiC-MOS with a large chip size and a Si-IGBT are driven by a single control signal;

FIG. 7 illustrates an allowable current when a SiC-MOS with a small chip size and a Si-IGBT are driven by a single control signal;

FIG. 8 illustrates an allowable current when a SiC-MOS and a Si-IGBT are driven by separate control signals;

FIG. 9 is a top view illustrating a part of the internal structure of the semiconductor device according to Embodiment 1;

FIG. 10 is a side view illustrating a part of the internal structure of the semiconductor device according to Embodiment 1; FIG. 11 is a top view illustrating a part of an internal structure of a semiconductor device according to Embodiment 2;

FIG. 12 is a side view illustrating a part of the internal structure of the semiconductor device according to Embodiment 2; and

FIG. 13 is a block diagram illustrating a configuration of a power conversion system to which a power conversion device according to Embodiment 3 has been applied.

### DESCRIPTION OF THE PREFERRED EMBODIMENTS

### Embodiment 1

### [Structure of Semiconductor Device]

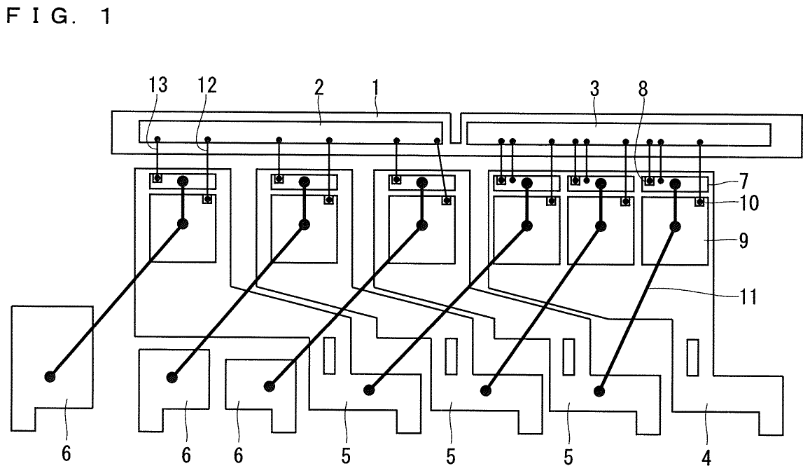

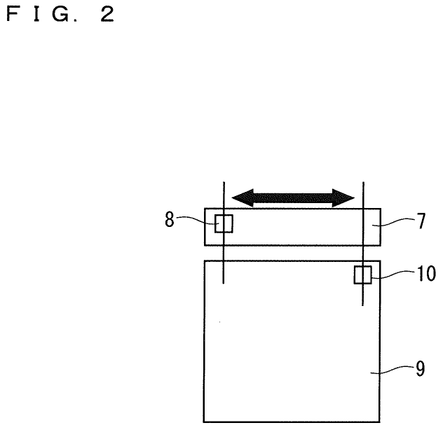

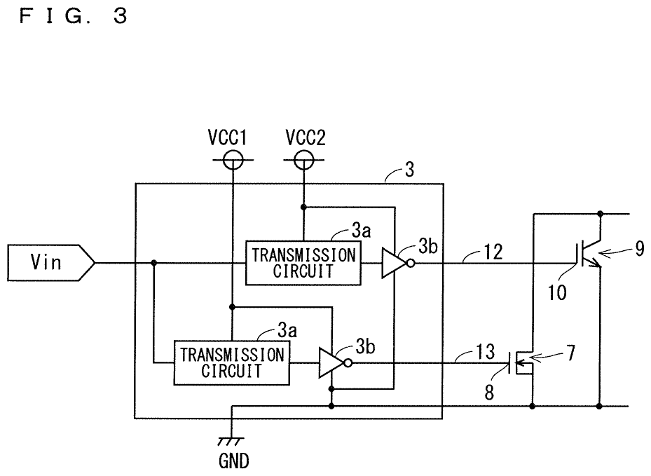

Embodiment 1 will be described with reference to the drawings. FIG. 1 is a top view illustrating an internal structure of a semiconductor device according to Embodiment 1. FIG. 2 is a top view illustrating a part of the internal structure of the semiconductor device according to Embodiment 1. FIG. 3 is a circuit diagram illustrating a part of a circuit configuration of the semiconductor device according to Embodiment 1.

The semiconductor device is included in a three-phase inverter, and includes a low voltage integrated circuit (LVIC) 2, a high voltage integrated circuit (HVIC) 3, six MOSFETs 7, six IGBTs 9, an IC frame 1, a high side frame 4, three low side frames 5, and three low side terminals 6 as illustrated in FIG. 1. Although the semiconductor device is plastic encapsulated to form a package, the plastic encapsulation is omitted in FIG. 1. Here, the HVIC 3 and the LVIC 2 correspond to control ICs. Furthermore, the MOSFETs 7 correspond to first semiconductor elements, and the IGBTs 9 correspond to second semiconductor elements. Each of the number of the MOSFETs 7 and the number of the IGBTs 9 is not limited to six.

The HVIC 3 and the LVIC 2 each being of a rectangle having a long side extending in the first direction in a top view are disposed on the IC frame 1. In FIG. 1, the HVIC 3 is on the right of the IC frame 1, and the LVIC 2 is on the left of the IC frame 1. Here, the first direction is the horizontal direction in FIG. 1.

The HVIC 3 controls driving of the three MOSFETs 7 and the three IGBTs 9 that are disposed on a high side. The LVIC 2 controls driving of the three MOSFETs 7 and the three IGBTs 9 that are disposed on a low side. Here, “disposed on a high side” means being disposed on the high side frame 4, and “disposed on a low side” means being disposed on the low side frames 5.

As illustrated in FIG. 3, the HVIC 3 includes two pairs of transmission circuits 3a and inverters 3b. The transmission circuit 3a and the inverter 3b in each of the pairs are serially connected to each other. An output electrode of one of the inverters 3b is connected to a gate pad 8 of the MOSFET 7 through a gate wire 13. An output electrode of the other inverter 3b is connected to a gate pad 10 of the IGBT 9 through a gate wire 12. In FIG. 3, the HVIC 3 is connected to the MOSFET 7 and the IGBT 9 on a one-by-one basis. However, the HVIC 3 is actually connected to the three MOSFETs 7 and the three IGBTs 9. The connection relationship between the LVIC 2, the MOSFETs 7, and the IGBTs 9, which is not illustrated, is identical to that of the HVIC 3. Thus, the description thereof is omitted.

The high side frame 4 and the three low side frames 5 are disposed in the first direction. The high side frame 4 is disposed on the right, and the three low side frames 5 are disposed on the left in FIG. 1. The three low side terminals 6 are disposed on the left of the three low side frames 5.

As illustrated in FIGS. 1 and 3, each of the MOSFETs 7 is connected in parallel with a corresponding one of the IGBTs 9. As illustrated in FIGS. 1 and 2, each of the MOSFETs 7 is of a rectangle having a long side extending in the first direction and a short side extending in a direction orthogonal to the first direction in a top view. The three MOSFETs 7 out of the six MOSFETs 7 are disposed side by side on the high side frame 4 in the first direction. The remaining three MOSFETs 7 are disposed on the respective three low side frames 5. Here, the direction orthogonal to the first direction is the vertical direction in FIG. 1.

Each of the IGBTs 9 is of a quadrangle having a side extending in the first direction in a top view. Specifically, each of the IGBTs 9 is of a rectangle having a short side extending in the first direction and a long side extending in the direction orthogonal to the first direction in a top view. The three IGBTs 9 out of the six IGBTs 9 are disposed side by side on the high side frame 4 in the first direction. The remaining three IGBTs 9 are disposed on the respective three low side frames 5.

The MOSFETs 7 and the IGBTs 9 are disposed so that the long side of each of the MOSFETs 7 faces the short side of a corresponding one of the IGBTs 9. Furthermore, the HVIC 3 (or the LVIC 2), the MOSFETs 7, and the IGBTs 9 are disposed in this order in the direction orthogonal to the first direction. Specifically, the HVIC 3 (or the LVIC 2), the MOSFETs 7, and the IGBTs 9 are disposed in this order from the top to the bottom in FIG. 1. This disposes the three MOSFETs 7 between the HVIC 3 and the three IGBTs 9 on the high side. This also disposes the three MOSFETs 7 between the LVIC 2 and the three IGBTs 9 on the low side.

The gate pad 8 is disposed on each of the MOSFETs 7. The gate pad 8 receives a signal for controlling driving of the MOSFET 7 from the HVIC 3 (or the LVIC 2). The HVIC 3 (or the LVIC 2) and the gate pad 8 are connected through the gate wire 13. Furthermore, an angle between the gate wire 13 and the first direction ranges from 80° to 100°. Here, the gate pad 8 corresponds to a first gate pad, and the gate wire 13 corresponds to a first wire.

The gate pad 10 is disposed on each of the IGBTs 9. The gate pad 10 receives a signal for controlling driving of the IGBT 9 from the HVIC 3 (or the LVIC 2). The HVIC 3 (or the LVIC 2) and the gate pad 10 are connected through the gate wire 12. Furthermore, an angle between the gate wire 12 and the first direction ranges from 80° to 100°. Here, the gate pad 10 corresponds to a second gate pad, and the gate wire 12 corresponds to a second wire.

A main current wire 11 electrically connects an emitter electrode on each of the IGBTs 9 to an emitter electrode on a corresponding one of the MOSFETs 7, and is connected to one of the low side terminals 6 (or the low side frames 5).

The gate pad 8 is disposed on each of the MOSFETs 7 on one side in the first direction, whereas the gate pad 10 is disposed on each of the IGBTs 9 on the other side in the first direction. Specifically, in FIGS. 1 and 2, the gate pad 8 is disposed at the left end on each of the MOSFETs 7, whereas the gate pad 10 is disposed at the right end on each of the IGBTs 9. An output electrode of the HVIC 3 (or the LVIC 2) to be connected to the gate pad 8 is disposed at a position facing the gate pad 8, whereas an output electrode of the HVIC 3 (or the LVIC 2) to be connected to the gate pad 10 is disposed at a position facing the gate pad 10.

This can route the gate wire 13 and the gate wire 12 without crossing each other. Moreover, the gate wire 12 that connects the HVIC 3 (or the LVIC 2) to the gate pad 10 disposed distant from the HVIC 3 (or the LVIC 2) can be routed with the shortest length without redundancy. This can consequently shorten the routing length of the gate wire 12. If each of the MOSFETs 7 includes a semiconductor substrate containing SiC, shrinking the MOSFET 7 facilitates reduction in the production costs. Furthermore, forming each of the MOSFETs 7 so that an aspect ratio of the long side to the short side of the MOSFET 7 is larger than 2:1 further shortens the routing length of the gate wire 12 between the HVIC 3 (or the LVIC 2) and the gate pad 10. This can facilitate downsizing the semiconductor device.

[Effects and Advantages]

Next, effects and advantages of the semiconductor device according to Embodiment 1 will be described in detail. As illustrated in FIGS. 1 to 3, the semiconductor device according to Embodiment 1 includes: the MOSFET 7 and the IGBT 9 that are connected in parallel with each other; the HVIC 3 and the LVIC 2 controlling driving of the MOSFET 7 and the IGBT 9, the HVIC 3 and the LVIC 2 each being of a rectangle having a long side extending in a first direction in a top view; the gate pad 8 disposed on the MOSFET 7 and receiving a signal for controlling the driving of the MOSFET 7; the gate pad 10 disposed on the IGBT 9 and receiving a signal for controlling the driving of the IGBT 9; the gate wire 13 connecting the HVIC 3 (or the LVIC 2) to the gate pad 8; and the gate wire 12 connecting the HVIC 3 (or the LVIC 2) to the gate pad 10. The MOSFET 7 is of a rectangle having a long side extending in the first direction in the top view, the IGBT 9 is of a quadrangle having a side extending in the first direction in the top view, the MOSFET 7 and the IGBT 9 are disposed so that the long side of the MOSFET 7 faces the side of the IGBT 9, and the HVIC 3 (or the LVIC 2), the MOSFET 7, and the IGBT 9 are disposed in this order in a direction orthogonal to the first direction, the gate pad 8 is disposed on the MOSFET 7 on one side in the first direction, and the gate pad 10 is disposed on the IGBT 9 on the other side in the first direction.

Furthermore, an angle between the gate wire 13 and the first direction and an angle between the gate wire 12 and the first direction each range from 80° to 100°.

This can shorten the routing length of the gate wire 12 that connects the HVIC 3 (or the LVIC 2) to the gate pad 10 of each of the IGBTs 9 disposed distant from the HVIC 3 (or the LVIC 2). This produces the following advantages.

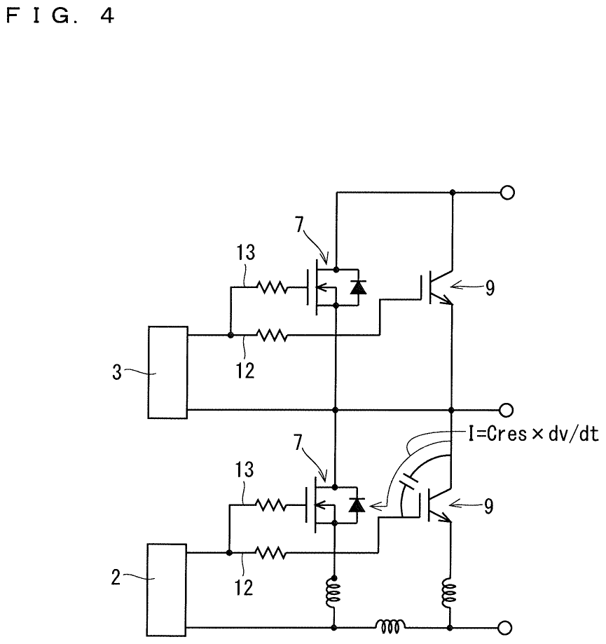

First, an advantage of reducing overvoltage breakdowns and malfunctions that are caused by a dV/dt of the MOSFETs 7 will be described with reference to FIG. 4. FIG. 4 is a circuit diagram illustrating causes of the overvoltage breakdowns and the malfunctions that are caused by the dV/dt of the MOSFETs 7.

As illustrated in FIG. 4, assume transition from an OFF state to an ON state of the IGBTs 9 and the MOSFETs 7 on the high side. When the IGBTs 9 and the MOSFETs 7 on the high side transition from the OFF state to the ON state, parasitic diodes in the MOSFETs 7 on the low side that is an opposing arm are reversely recovered, and a collector-emitter voltage (a drain-source voltage) of the IGBTs 9 and the MOSFETs 7 on the low side increases. These create a dV/dt of the IGBTs 9 and the MOSFETs 7 on the high side which corresponds to the switching time.

Each of the MOSFETs 7 and the IGBTs 9 has a feedback capacitance Cres. A

displacement current I=Cres×dV/dt is generated through this Cres. Multiplication of the wiring impedance of the gate wire 12 of the IGBT 9 (and the gate wire 13 of the MOSFET 7) and the displacement current I temporarily increases a gate-emitter voltage of the IGBTs 9 and the MOSFETs 7 on the low side. This produces the overvoltage breakdowns and the malfunctions.

As the routing length of the gate wire 12 of the IGBT 9 (the gate wire 13 of the MOSFET 7) is shorter, the effect of reducing the wiring impedance is more enhanced. Thus, suppressing an increase in the gate-emitter voltage of the IGBTs 9 and the MOSFETs 7 on the low side can reduce the overvoltage breakdowns and the malfunctions.

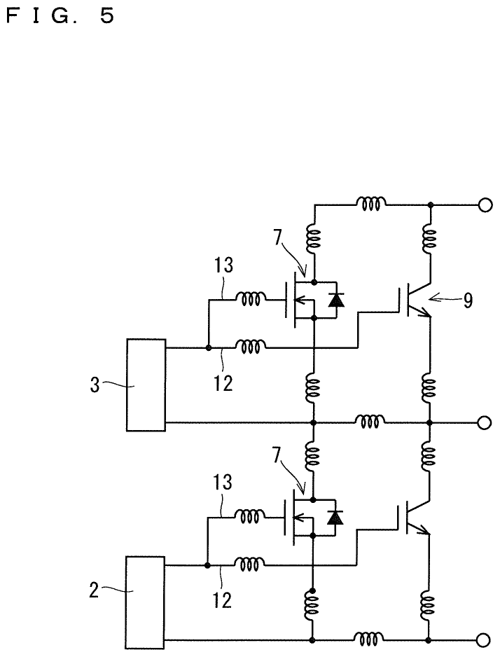

Next, an advantage of reducing parasitic oscillations when the MOSFET 7 and the IGBT 9 are driven in parallel will be described with reference to FIG. 5. FIG. 5 is a circuit diagram illustrating the parasitic oscillations when the MOSFET 7 and the IGBT 9 are driven in parallel.

As illustrated in FIG. 5, parasitic inductance components in a main circuit cause oscillations in switching operations when the MOSFET 7 and the IGBT 9 are driven in parallel. Thus, a design for bringing these parasitic inductance components closer to zero as much as possible is required.

Since the gate wire 12 of each of the IGBTs 9 can be designed shorter than conventional wires, reduction in the wiring inductance of the gate wires 12 can reduce parasitic oscillations. Driving the MOSFET 7 and the IGBT 9 in parallel may be replaced by driving the two MOSFETs 7 in parallel or driving the two IGBT 9 in parallel.

Next, an advantage of reducing wire sweeps in a step of injecting a mold resin will be described. Since the gate wire 12 of each of the IGBTs 9 can be designed shorter than the conventional wires, wire sweeps in the step of injecting a mold resin can be reduced. This can improve assembly properties of products.

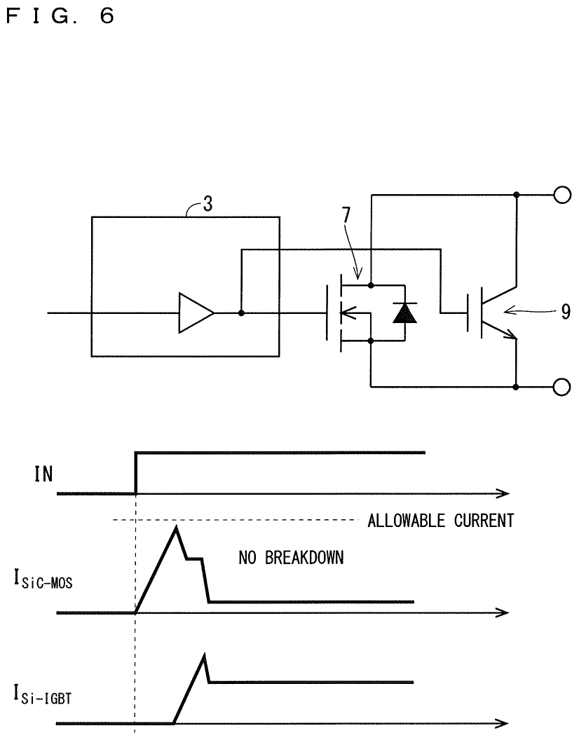

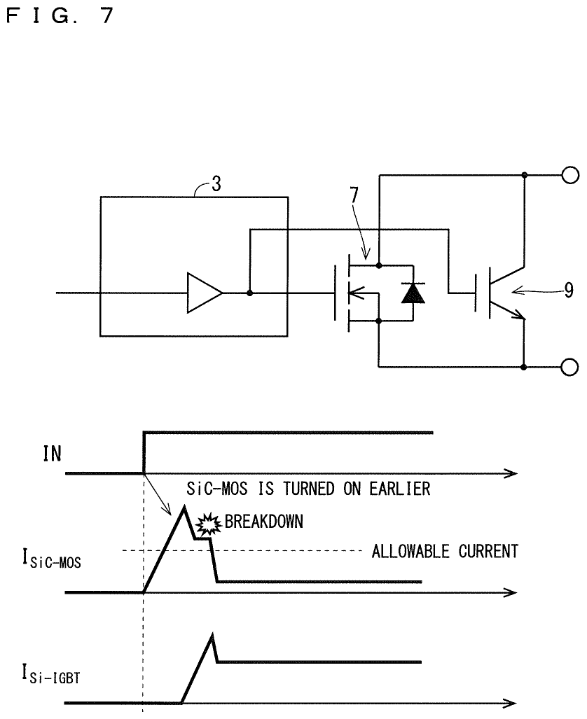

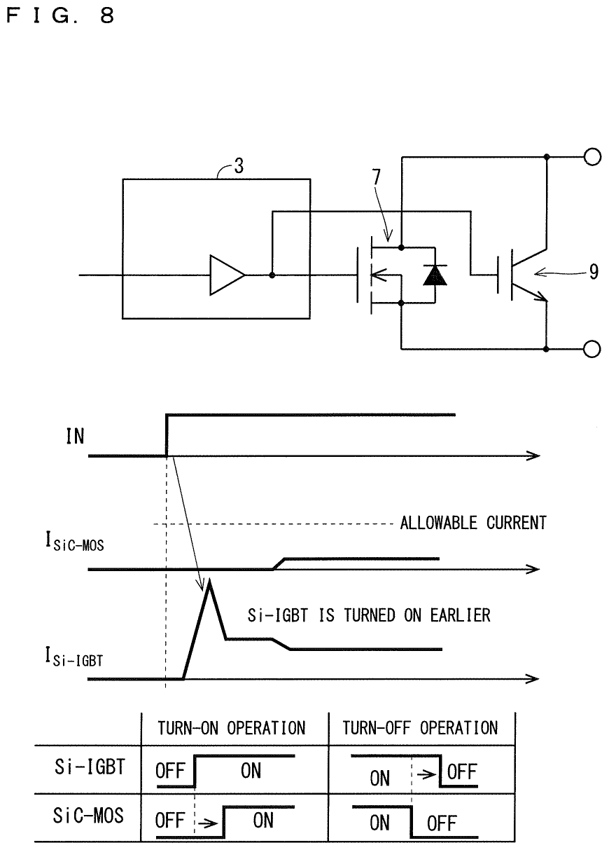

Next, an advantage of reducing breakdowns of the MOSFETs 7 caused by current balance control in diverting a current will be described with reference to FIGS. 6 to 8. FIG. 6 illustrates an allowable current when a SiC-MOS with a large chip size and a Si-IGBT are driven by a single control signal. FIG. 7 illustrates an allowable current when a SiC-MOS with a small chip size and a Si-IGBT are driven by a single control signal. FIG. 8 illustrates an allowable current when a SiC-MOS and a Si-IGBT are driven by separate control signals.

FIGS. 6 to 8 each illustrate the MOSFET 7 as a SiC-MOS and the IGBT 9 as a Si-IGBT.

Conventionally, the current balance control has not been possible because a single gate signal controls two power chips. When a SiC-MOS has a large chip size as illustrated in FIG. 6, the SiC-MOS is turned ON and then an I_{SiC-MOS} flows. Since the I_{SiC-MOS} is smaller than or equal to the allowable current of the SiC-MOS, normal operations have been possible. However, when a SiC-MOS has a small chip size as illustrated in FIG. 7, the SiC-MOS is turned ON earlier and then an I_{SiC-MOS} flows. However, the allowable current decreases, and the I_{SiC-MOS} exceeds the allowable current of the SiC-MOS. This causes a problem of thermal breakdowns in the SiC-MOS.

In contrast, two power chips are driven by separate control signals in Embodiment 1. As illustrated in FIG. 8, the Si-IGBT is turned ON earlier. Even when the SiC-MOS has a small chip size, the I_{SiC-MOS} is smaller than or equal to the allowable current of the SiC-MOS. Thus, the aforementioned problem can be solved.

[Other Advantages]

Next, advantages other than the advantages of shortening the routing length of the gate wire 12 will be described.

Since the MOSFET 7 contains SiC, the electrical characteristics of products can be improved.

Furthermore, since the MOSFET 7 is smaller in chip area than the IGBT 9 in a top view, the product costs can be reduced.

Furthermore, since the aspect ratio of the long side to the short side of the MOSFET 7 is larger than 2:1, the routing length of the gate wire 12 between the HVIC 3 (or the LVIC 2) and the gate pad 10 is further shortened. This facilitates downsizing semiconductor devices.

### Embodiment 2

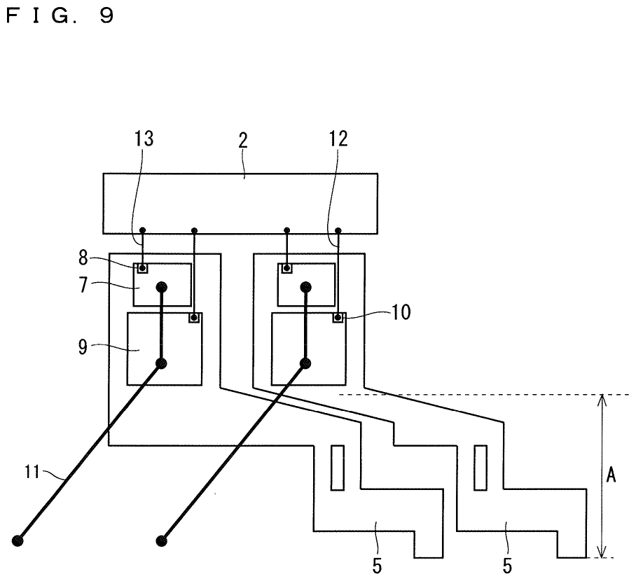

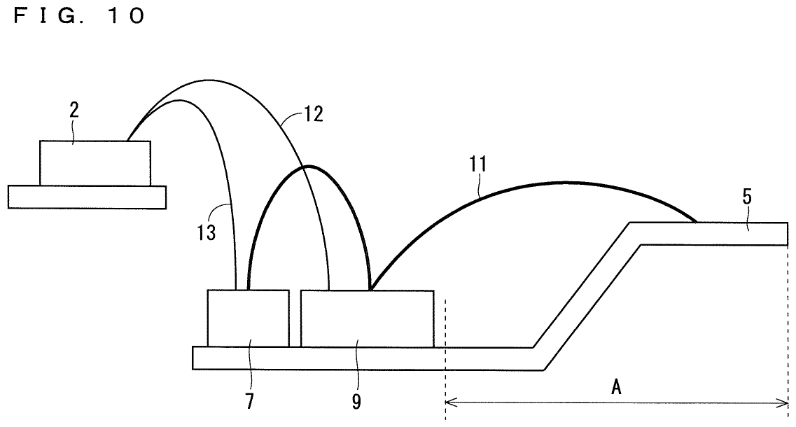

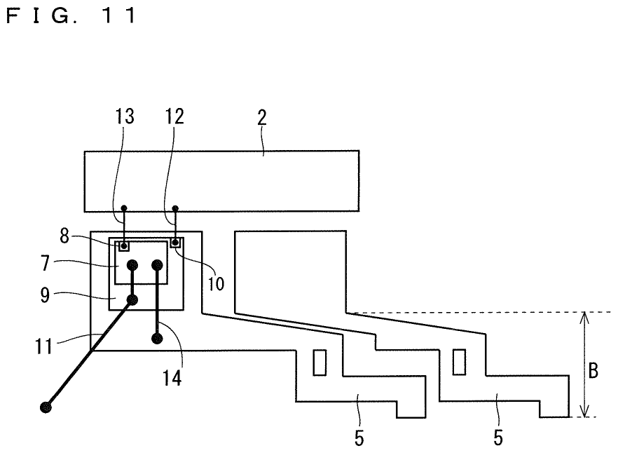

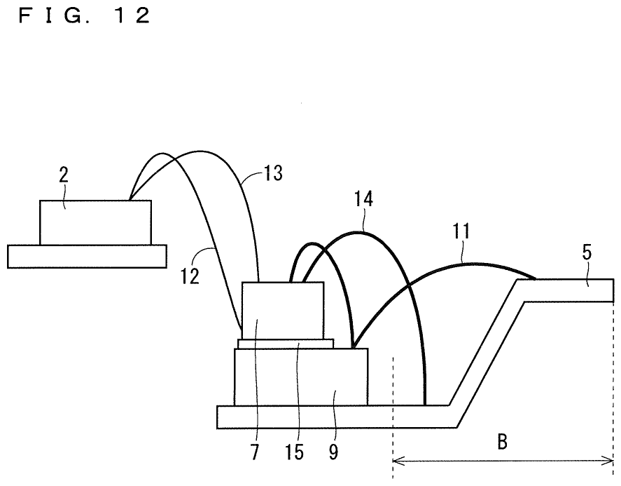

Next, a semiconductor device according to Embodiment 2 will be described. FIG. 9 is a top view illustrating a part of the internal structure of the semiconductor device according to Embodiment 1. FIG. 10 is a side view illustrating a part of the internal structure of the semiconductor device according to Embodiment 1. FIG. 11 is a top view illustrating a part of an internal structure of the semiconductor device according to Embodiment 2. FIG. 12 is a side view illustrating a part of the internal structure of the semiconductor device according to Embodiment 2. Each of FIGS. 9 to 12 illustrates only the low side. Since the high side and the low side have the same positional relationship between the MOSFETs 7 and the IGBTs 9, only the low side will be described herein. In Embodiment 2, the same reference numerals are applied to the same constituent elements described in Embodiment 1, and the description thereof is omitted.

[Structure of Semiconductor Device]

As illustrated in FIGS. 9 and 10, the MOSFETs 7 and the IGBTs 9 are disposed on the respective low side frames 5 in Embodiment 1.

In contrast, the IGBTs 9 are disposed on the respective low side frames 5, and the MOSFETs 7 are disposed on the respective IGBTs 9 through an insulator 15, as illustrated in FIGS. 11 and 12 in Embodiment 2. The MOSFETs 7 in Embodiment 1 have a vertical structure, whereas the MOSFETs 7 in Embodiment 2 have a horizontal structure in which a drain electrode, a source electrode, and a gate electrode are formed on the same plane.

The main current wire 11 electrically connects an emitter electrode on each of the IGBTs 9 to an emitter electrode on a corresponding one of the MOSFETs 7, and is connected to one of the low side terminals 6. Furthermore, a main current wire 14 electrically connects a collector electrode on each of the MOSFETs 7 to a corresponding one of the low side frames 5.

[Effects and Advantages]

The semiconductor device according to Embodiment 2 includes: the MOSFET 7 and the IGBT 9 that are connected in parallel with each other; the HVIC 3 and the LVIC 2 controlling driving of the MOSFET 7 and the IGBT 9, the HVIC 3 and the LVIC 2 each being of a rectangle having a long side extending in a first direction in a top view; the gate pad 8 disposed on the MOSFET 7 and receiving a signal for controlling the driving of the MOSFET 7; the gate pad 10 disposed on the IGBT 9 and receiving a signal for controlling the driving of the IGBT 9; the gate wire 13 connecting the HVIC 3 (or the LVIC 2) to the gate pad 8; and the gate wire 12 connecting the HVIC 3 (or the LVIC 2) to the gate pad 10. The MOSFET 7 is of a rectangle having a long side extending in the first direction in the top view, the IGBT 9 is of a quadrangle having a side extending in the first direction in the top view, the MOSFET 7 is disposed on the IGBT 9 through the insulator 15, the gate pad 8 is disposed on the MOSFET 7 on one side in the first direction, and the gate pad 10 is disposed on the IGBT 9 on the other side in the first direction.

This can shorten the routing length of the gate wire 12 that connects the HVIC 3 (or the LVIC 2) to the gate pad 10 of each of the IGBTs 9 disposed distant from the HVIC 3 (or the LVIC 2), similarly to that according to Embodiment 1.

This can produce advantages of reducing overvoltage breakdowns and malfunctions that are caused by a dV/dt of the MOSFETs 7, reducing parasitic oscillations when the MOSFET and the IGBT are driven in parallel, reducing wire sweeps in a step of injecting a mold resin, and reducing breakdowns of the MOSFETs 7 caused by current balance control in diverting a current.

Furthermore, reduction in a die-bonding area of the low side frame 5 on which the MOSFET 7 and the IGBT 9 are disposed as illustrated in FIGS. 11 and 12 according to Embodiment 2 more than that as illustrated in FIGS. 9 and 10 according to Embodiment 1 can shorten a length B of the low side frame 5 except the die-bonding area in FIGS. 11 and 12 more than a length A in FIGS. 9 and 10. The high side frame 4 with the same structure, which is not illustrated, can produce the same advantage. This can downsize semiconductor devices more than those by Embodiment 1.

### Embodiment 3

Embodiment 3 will describe a power conversion device to which the semiconductor devices according to Embodiments 1 and 2 are applied. Although the power conversion device to which the semiconductor devices according to Embodiments 1 and 2 are applied is not limited to a specific power conversion device, Embodiment 3 will describe application of the semiconductor devices according to Embodiments 1 and 2 to a three-phase inverter.

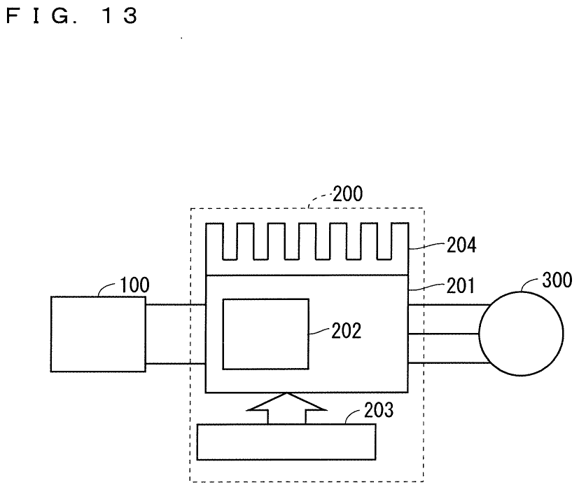

FIG. 13 is a block diagram illustrating a configuration of a power conversion system to which the power conversion device according to Embodiment 3 has been applied.

The power conversion system illustrated in FIG. 13 includes a power supply 100, a power conversion device 200, and a load 300. The power supply 100, which is a DC power supply, supplies a DC power to the power conversion device 200. The power supply 100 may include various components such as a DC system, a solar battery, or a rechargeable battery, and a rectifying circuit connected to an AC system, or an AC/DC converter. The power supply 100 may include a DC/DC converter which converts the DC power output from the DC system into a predetermined power.

The power conversion device 200, which is a three-phase inverter connected between the power supply 100 and the load 300, converts the DC power supplied from the power supply 100 into the AC power to supply the AC power to the load 300. As illustrated in FIG. 13, the power conversion device 200 includes a main conversion circuit 201 that converts the DC power into the AC power, and a control circuit 203 that outputs, to the main conversion circuit 201, a control signal for controlling the main conversion circuit 201.

The load 300 is a three-phase electrical motor driven by the AC power supplied from the power conversion device 200. The load 300 is not limited to specific use but is an electrical motor mounted on various types of electrical devices. Thus, the load 300 is used as an electrical motor for, for example, a hybrid car, an electrical car, a rail vehicle, an elevator, or air-conditioning equipment.

The power conversion device 200 will be described in detail hereinafter. The main conversion circuit 201 includes switching elements (not illustrated) and free-wheeling diodes (not illustrated). Switching of the switching element causes the DC power supplied from the power supply 100 to be converted into the AC power. The main conversion circuit 201 then supplies the AC power to the load 300. The specific circuit configuration of the main conversion circuit 201 is of various types. The main conversion circuit 201 according to Embodiment 3 is a three-phase full-bridge circuit having two levels, and includes six switching elements and six free-wheeling diodes anti-parallel connected to the respective switching elements. A semiconductor module 202 corresponding to the semiconductor device according to any one of Embodiments 1 and 2 is applied to at least one of the switching elements and the free-wheeling diodes in the main conversion circuit 201. The six switching elements form three pairs of upper and lower arms in each pair of which the two switching elements are serially connected to each other. The three pairs of upper and lower arms form the respective phases (U-phase, V-phase, and W-phase) of the full-bridge circuit. Output terminals of the respective pairs of upper and lower arms, i.e., three output terminals of the main conversion circuit 201 are connected to the load 300.

The main conversion circuit 201 includes a drive circuit (not illustrated) that drives each of the switching elements. The drive circuit may be included in the semiconductor module 202 or provided separately from the semiconductor module 202. The drive circuit generates drive signals for driving the switching elements of the main conversion circuit 201, and supplies the drive signals to control electrodes of the switching elements of the main conversion circuit 201. Specifically, the drive circuit outputs the drive signal for switching each of the switching elements to an ON state and the drive signal for switching the switching element to an OFF state, to the control electrode of the switching element in accordance with the control signal from the control circuit 203 to be described later. When the switching element is kept in the ON state, the drive signal is a voltage signal (ON signal) higher than or equal to a threshold voltage of the switching element. When the switching element is kept in the OFF state, the drive signal is a voltage signal (OFF signal) lower than or equal to the threshold voltage of the switching element.

The control circuit 203 controls the switching elements of the main conversion circuit 201 to supply a desired power to the load 300. Specifically, the control circuit 203 calculates a time (ON time) when each of the switching elements of the main conversion circuit 201 needs to enter the ON state, based on the power which needs to be supplied to the load 300. For example, the control circuit 203 can control the main conversion circuit 201 by performing PWN control for modulating the ON time of the switching elements in accordance with the voltage which needs to be output. Then, the control circuit 203 outputs a control instruction (control signal) to the drive circuit included in the main conversion circuit 201 so that the drive circuit outputs the ON signal to the switching element which needs to enter the ON state and outputs the OFF signal to the switching element which needs to enter the OFF state at each time. The drive circuit outputs the ON signal or the OFF signal as the drive signal to the control electrode of each of the switching elements in accordance with this control signal.

A radiating fin 204 radiates outside the heat generated by driving of the semiconductor module 202. Specifically, bonding grease is applied between the radiating fin 204 and the semiconductor module 202 to radiate outside the heat generated by the semiconductor module 202, using thermal conductivity of the radiating fin 204 and the bonding grease. The radiating fin 204 may be attached to only one side surface or both side surfaces of the semiconductor module 202.

Since the semiconductor devices according to Embodiments 1 and 2 are applied to the switching elements and the free-wheeling diodes in the main conversion circuit 201, the power conversion device 200 according to Embodiment 3 can be downsized.

Although Embodiment 3 describes the example of applying the semiconductor devices according to Embodiments 1 and 2 to the three-phase inverter having the two levels, application of the semiconductor devices according to Embodiments 1 and 2 is not limited to this. The semiconductor devices according to Embodiments 1 and 2 are applicable to various power conversion devices. Although Embodiment 3 describes the power conversion device 200 having the two levels, the power conversion device 200 may have three or multiple levels. The semiconductor devices according to Embodiments 1 and 2 may be applied to a single-phase inverter when the power is supplied to a single-phase load. The semiconductor devices according to Embodiments 1 and 2 are also applicable to a DC/DC converter or an AC/DC converter when the power is supplied to, for example, a DC load.

The load 300 for the power conversion device 200 to which the semiconductor devices according to Embodiments 1 and 2 are applied is not limited to an electrical motor. The power conversion device 200 is also applicable as a power-supply device of an electrical discharge machine, a laser beam machine, an induction heat cooking device, or a non-contact power feeding system, and is further applicable as a power conditioner of, for example, a solar power system or an electricity storage system.

Embodiments can be freely combined, and appropriately modified or omitted.

The following will describe a summary of various aspects of the present disclosure as appendixes.

Appendix 1

A semiconductor device, comprising:
a first semiconductor element and a second semiconductor element that are connected in parallel with each other;
a control integrated circuit controlling driving of the first semiconductor element and the second semiconductor element, the control integrated circuit being of a rectangle having a long side extending in a first direction in a top view;
a first gate pad disposed on the first semiconductor element and receiving a signal for controlling the driving of the first semiconductor element;
a second gate pad disposed on the second semiconductor element and receiving a signal for controlling the driving of the second semiconductor element;
a first wire connecting the control integrated circuit to the first gate pad; and
a second wire connecting the control integrated circuit to the second gate pad,
wherein the first semiconductor element is of a rectangle having a long side extending in the first direction in the top view,
the second semiconductor element is of a quadrangle having a side extending in the first direction in the top view,
the first semiconductor element and the second semiconductor element are disposed so that the long side of the first semiconductor element faces the side of the second semiconductor element, and the control integrated circuit, the first semiconductor element, and the second semiconductor element are disposed in this order in a direction orthogonal to the first direction,
the first gate pad is disposed on the first semiconductor element on one side in the first direction, and
the second gate pad is disposed on the second semiconductor element on the other side in the first direction.

[Appendix 2]

The semiconductor device according to appendix 1,
wherein an angle between the first wire and the first direction and an angle between the second wire and the first direction each range from 80° to 100°.

[Appendix 3]

The semiconductor device according to appendix 1 or 2,
wherein the first semiconductor element contains SiC.

[Appendix 4]

The semiconductor device according to one of appendixes 1 to 3,
wherein the first semiconductor element is smaller in chip area than the second semiconductor element in the top view.

[Appendix 5]

The semiconductor device according to one of appendixes 1 to 4,
wherein an aspect ratio of the long side to a short side of the first semiconductor element is larger than 2:1.

[Appendix 6]

A semiconductor device, comprising:
a first semiconductor element and a second semiconductor element that are connected in parallel with each other;
a control integrated circuit controlling driving of the first semiconductor element and the second semiconductor element, the control integrated circuit being of a rectangle having a long side extending in a first direction in a top view;
a first gate pad disposed on the first semiconductor element and receiving a signal for controlling the driving of the first semiconductor element;
a second gate pad disposed on the second semiconductor element and receiving a signal for controlling the driving of the second semiconductor element;
a first wire connecting the control integrated circuit to the first gate pad; and
a second wire connecting the control integrated circuit to the second gate pad,
wherein the first semiconductor element is of a rectangle having a long side extending in the first direction in the top view,
the second semiconductor element is of a quadrangle having a side extending in the first direction in the top view,
the first semiconductor element is disposed on the second semiconductor element through an insulator,
the first gate pad is disposed on the first semiconductor element on one side in the first direction, and
the second gate pad is disposed on the second semiconductor element on the other side in the first direction.

[Appendix 7]

The semiconductor device according to any one of appendixes 1 to 6,
wherein the first semiconductor element is a metal-oxide-semiconductor field-effect transistor, and the second semiconductor element is an insulated gate bipolar transistor.

[Appendix 8]

A power conversion device, comprising:
a main conversion circuit including the semiconductor device according to any one of appendixes 1 to 7, the main conversion circuit converting an input power to output a resulting power;
a control circuit outputting, to the main conversion circuit, a control signal for controlling the main conversion circuit; and
a radiating fin radiating outside heat generated by driving of the semiconductor device.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a first semiconductor element and a second semiconductor element that are connected in parallel with each other;
a control integrated circuit controlling driving of the first semiconductor element and the second semiconductor element, the control integrated circuit being of a rectangle having a long side extending in a first direction in a top view;
a first gate pad disposed on the first semiconductor element and receiving a signal for controlling the driving of the first semiconductor element;
a second gate pad disposed on the second semiconductor element and receiving a signal for controlling the driving of the second semiconductor element;
a first wire connecting the control integrated circuit to the first gate pad; and
a second wire connecting the control integrated circuit to the second gate pad,
wherein the first semiconductor element is of a rectangle having a long side extending in the first direction in the top view,
the second semiconductor element is of a quadrangle having a side extending in the first direction in the top view,
the first semiconductor element and the second semiconductor element are disposed so that the long side of the first semiconductor element faces the side of the second semiconductor element, and the control integrated circuit, the first semiconductor element, and the second semiconductor element are disposed in this order in a direction orthogonal to the first direction,
the first gate pad is disposed on the first semiconductor element on one side in the first direction, and
the second gate pad is disposed on the second semiconductor element on the other side in the first direction.

2. The semiconductor device according to claim 1,
wherein an angle between the first wire and the first direction and an angle between the second wire and the first direction each range from 80° to 100°.

3. The semiconductor device according to claim 1,
wherein the first semiconductor element contains SiC.

4. The semiconductor device according to claim 1,
wherein the first semiconductor element is smaller in chip area than the second semiconductor element in the top view.

5. The semiconductor device according to claim 1,
wherein an aspect ratio of the long side to a short side of the first semiconductor element is larger than 2:1.

6. A semiconductor device, comprising:
a first semiconductor element and a second semiconductor element that are connected in parallel with each other;
a control integrated circuit controlling driving of the first semiconductor element and the second semiconductor element, the control integrated circuit being of a rectangle having a long side extending in a first direction in a top view;
a first gate pad disposed on the first semiconductor element and receiving a signal for controlling the driving of the first semiconductor element;
a second gate pad disposed on the second semiconductor element and receiving a signal for controlling the driving of the second semiconductor element;
a first wire connecting the control integrated circuit to the first gate pad; and
a second wire connecting the control integrated circuit to the second gate pad,
wherein the first semiconductor element is of a rectangle having a long side extending in the first direction in the top view,
the second semiconductor element is of a quadrangle having a side extending in the first direction in the top view,
the first semiconductor element is disposed on the second semiconductor element through an insulator,
the first gate pad is disposed on the first semiconductor element on one side in the first direction, and
the second gate pad is disposed on the second semiconductor element on the other side in the first direction.

7. The semiconductor device according to claim 1,
wherein the first semiconductor element is a metal-oxide-semiconductor field-effect transistor, and the second semiconductor element is an insulated gate bipolar transistor.

8. The semiconductor device according to claim 6,
wherein the first semiconductor element is a metal-oxide-semiconductor field-effect transistor, and the second semiconductor element is an insulated gate bipolar transistor.

9. A power conversion device, comprising:
a main conversion circuit including the semiconductor device according to claim 1, the main conversion circuit converting an input power to output a resulting power;
a control circuit outputting, to the main conversion circuit, a control signal for controlling the main conversion circuit; and
a radiating fin radiating outside heat generated by driving of the semiconductor device.

10. A power conversion device, comprising:
a main conversion circuit including the semiconductor device according to claim 6, the main conversion circuit converting an input power to output a resulting power;
a control circuit outputting, to the main conversion circuit, a control signal for controlling the main conversion circuit; and
a radiating fin radiating outside heat generated by driving of the semiconductor device.
